(19) United States
(12) Patent Application Publication
(10) Pub. No.: US 2026/0262528 A1
(43) Pub. Date: Sep. 3, 2026

(54) SEMICONDUCTOR STRUCTURE AND MANUFACTURING METHOD THREREOF

(71) Applicant: SILICONWARE PRECISION INDUSTRIES CO., LTD., Taichung City (TW)

(72) Inventors: Chin-Wen CHEN, Taichung City (TW); Che-Yang LEE, Taichung City (TW); Yi-Ta TSAI, Taichung City (TW)

(73) Assignee: SILICONWARE PRECISION INDUSTRIES CO., LTD., Taichung City (TW)

(21) Appl. No.: 19/323,766

(22) Filed: Sep. 9, 2025

(30) Foreign Application Priority Data
Mar. 3, 2025 (TW) 114107724

(51) Int. Cl. H01L 23/00

(52) U.S. Cl. CPC H10W 72/20; H10W 72/012; H10W 72/90; H10W 72/01255; H10W 72/227; H10W 72/248; H10W 72/267; H10W 72/29

(57) ABSTRACT

Disclosed are a semiconductor structure and a manufacturing method thereof, in which a semiconductor substrate defined with an active area and an idle area adjacent to each other is provided. A plurality of semiconductor substrate units are disposed on the active area, and each of the semiconductor substrate units is defined with an electrical contact dense area and an electrical contact sparse area. A plurality of conductive bumps are formed on each of the semiconductor substrate units in the active area by electroplating, and a plurality of current control bumps are formed in the idle area by electroplating, so as to avoid a problem of uneven electroplating current distribution.

### BACKGROUND

### 1. Technical Field

The present disclosure relates to a semiconductor device, and more particularly, to a wafer-type semiconductor structure and a manufacturing method thereof. 2. Description of Related Art

With the development of industrial applications, the functions required by electronic components for high-speed computing, artificial intelligence and the like have become increasingly diversified, and the performance of the electronic components has become increasingly higher. Therefore, it is necessary to integrate and package multiple heterogeneous chips and to develop towards large-size packaging with high stacking number, high density, high I/O number and high pin number.

Conventional large-scale electronic packages, such as CoWoS (Chip on Wafer on Substrate) electronic packages, are characterized in that a through silicon interposer (TSI) is disposed on a flip-chip side of a package substrate, and at least one semiconductor chip is disposed on the TSI. The TSI has a plurality of conductive bumps for combining the semiconductor chip or the package substrate.

However, the afore-mentioned TSI is made of silicon wafers. In the manufacturing process of the plurality of conductive bumps, the distribution area and density of the plurality of conductive bumps are not fixed in response to actual application requirements. Therefore, when electroplating the plurality of conductive bumps, the heights of the plurality of conductive bumps are often inconsistent due to uneven current distribution (current is too concentrated or dispersed). Especially, the TSI may crack due to uneven stress distribution during the manufacturing process.

Therefore, how to overcome the above-mentioned drawbacks of the prior art has become an urgent issue to be solved.

### SUMMARY

In view of the various deficiencies of the prior art, the present disclosure provides a semiconductor structure, which comprises: a semiconductor substrate defined with an active area and an idle area, wherein a plurality of semiconductor substrate units are disposed on the active area, and each of the semiconductor substrate units is defined with an electrical contact dense area and an electrical contact sparse area; a plurality of conductive bumps formed on each of the semiconductor substrate units in the active area; and a plurality of current control bumps formed on the idle area, wherein a density of the plurality of conductive bumps in the electrical contact dense areas is higher than a density of the plurality of current control bumps in the idle area, and the density of the plurality of current control bumps in the idle area is higher than a density of the plurality of conductive bumps in the electrical contact sparse areas.

The present disclosure further provides a method of manufacturing a semiconductor structure, which comprises: providing a semiconductor substrate defined with an active area and an idle area adjacent to each other, wherein a plurality of semiconductor substrate units are disposed on the active area, and each of the semiconductor substrate units is defined with an electrical contact dense area and an electrical contact sparse area; forming a plurality of conductive bumps on each of the semiconductor substrate units in the active area; and forming a plurality of current control bumps on the idle area, wherein a density of the plurality of conductive bumps in the electrical contact dense areas is higher than a density of the plurality of current control bumps in the idle area, and the density of the plurality of current control bumps in the idle area is higher than a density of the plurality of conductive bumps in the electrical contact sparse areas.

In the aforementioned semiconductor structure and the manufacturing method thereof, a plurality of electrical connection pads are disposed on each of the semiconductor substrate units in the active area.

In the aforementioned semiconductor structure and the manufacturing method thereof, an insulating layer is disposed on the semiconductor substrate, and the insulating layer is formed with a plurality of openings to expose the plurality of electrical connection pads.

In the aforementioned semiconductor structure and the manufacturing method thereof, the present disclosure further comprises forming a conductive layer on the insulating layer and the plurality of electrical connection pads.

In the aforementioned semiconductor structure and the manufacturing method thereof, the conductive layer is an under-bump metallization.

In the aforementioned semiconductor structure and the manufacturing method thereof, the present disclosure further comprises forming a resist layer on the conductive layer, wherein a plurality of first openings are formed on the resist layer in the active area to expose the conductive layer corresponding to the plurality of electrical connection pads, and a plurality of second openings are formed on the resist layer in the idle area to form a current control pattern and expose the conductive layer corresponding to a portion of the insulating layer.

In the aforementioned semiconductor structure and the manufacturing method thereof, the present disclosure further comprises forming the plurality of conductive bumps in the plurality of first openings, and forming the plurality of current control bumps in the plurality of second openings.

In the aforementioned semiconductor structure and the manufacturing method thereof, the present disclosure further comprises removing the resist layer and the conductive layer covered by the resist layer.

In the aforementioned semiconductor structure and the manufacturing method thereof, a density of the plurality of conductive bumps in the electrical contact dense areas is more than twice that in the electrical contact sparse areas.

As can be seen from the above, in the semiconductor structure and the manufacturing method thereof according to the present disclosure, the plurality of first openings of the resist layer are formed in the active area of the semiconductor substrate, while the plurality of second openings of the resist layer are formed in the idle area of the semiconductor substrate (forming the current control pattern) when the plurality of conductive bumps are formed by electroplating. Then, the plurality of current control bumps are formed by electroplating to distribute the electroplating current and to avoid inconsistencies in the height and flatness of the plurality of conductive bumps caused by uneven electroplating current distribution.

### BRIEF DESCRIPTION OF THE DRAWINGS

FIG. 1 to FIG. 6 are schematic cross-sectional and plan views illustrating a semiconductor structure and a manufacturing method thereof according to the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

Please refer to FIG. 1 to FIG. 6, which are schematic cross-sectional and plan views illustrating a semiconductor structure and a manufacturing method thereof according to the present disclosure. The semiconductor structure of the present disclosure is a monolithic structure, such as a wafer form.

As shown in FIG. 1, a semiconductor substrate 10 (such as a wafer, a silicon substrate or a glass substrate) is provided, which is defined with an active area 10a and an idle area 10b adjacent to each other. The active area 10a is provided with a plurality of semiconductor substrate units 100 (such as wafers), while the semiconductor substrate 10 in the idle area 10b has no complete semiconductor substrate unit 100.

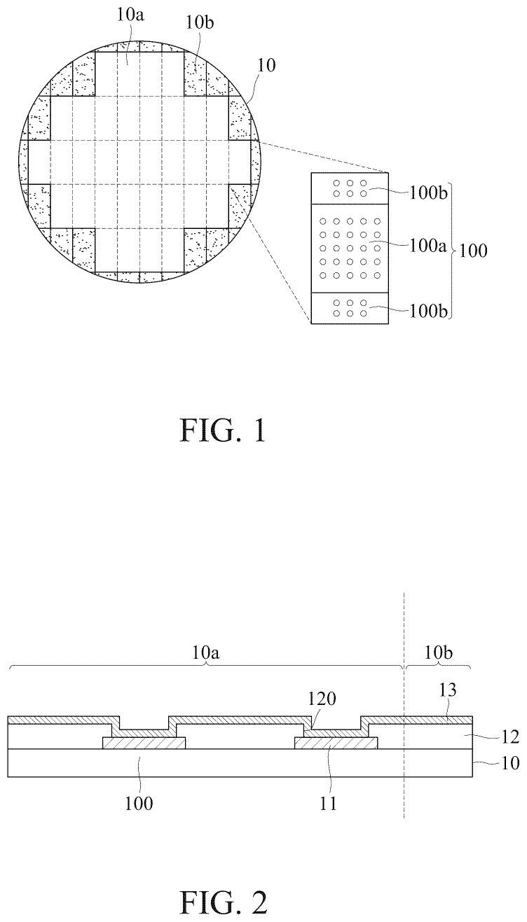

Please refer to FIG. 2 at the same time, which is a partial cross-sectional schematic diagram of the semiconductor substrate 10 of FIG. 1. A plurality of electrical connection pads 11 are disposed on a surface of each semiconductor substrate unit 100 corresponding to the active area 10a. The plurality of electrical connection pads 11 may be disposed only in the active area 10a and not in the idle area 10b, or may be disposed in both the active area 10a and the idle area 10b. An insulating layer 12 is disposed on the entire semiconductor substrate 10, and the insulating layer 12 is formed with a plurality of openings 120 to expose the plurality of electrical connection pads 11. In one embodiment, a material forming the electrical connection pad 11 may be aluminum, and a material forming the insulating layer 12 may be polyimide (PI), benezocy-clobutene (BCB) or polybenzoxazole (PBO).

In addition, each of the semiconductor substrate units 100 is further defined with an electrical contact dense area 100a and electrical contact sparse areas 100b. A density of the plurality of electrical connection pads 11 in the electrical contact dense areas 100a is more than twice that in the electrical contact sparse areas 100b.

Then, a conductive layer 13 is formed on the insulating layer 12 and the plurality of electrical connection pads 11 exposed from the openings 120 of the insulating layer 12. The conductive layer 13 may be used as an under-bump metallization (UBM). In one embodiment, a material forming the conductive layer 13 may be titanium/copper (Ti/Cu) or titanium/tungsten/copper (Ti/W/Cu).

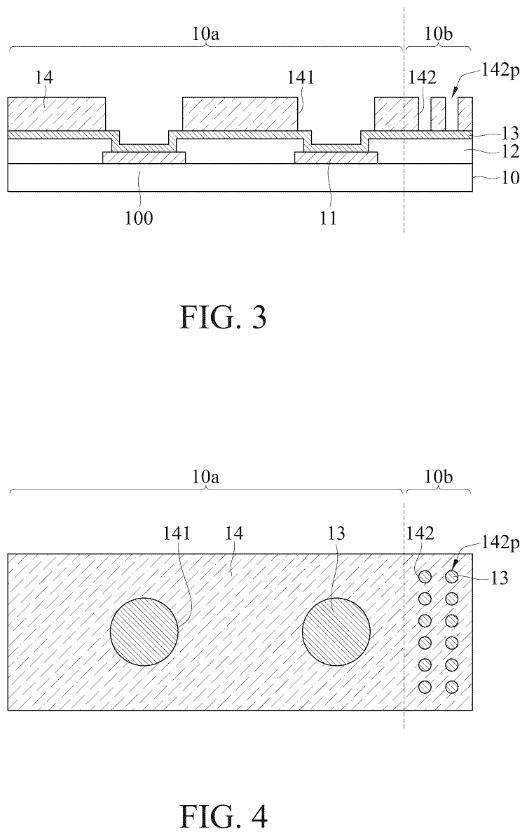

As shown in FIG. 3 and FIG. 4 that is a partial top schematic diagram of FIG. 3. Then, a patterned resist layer 14 is formed on the conductive layer 13. The resist layer 14 is formed with a plurality of first openings 141 in the active area 10a to expose the conductive layer 13 corresponding to the plurality of electrical connection pads 11. The resist layer 14 is formed with a plurality of second openings 142 in the idle area 10b to expose the conductive layer 13 corresponding to a portion of the insulating layer 12, so as to form a current control pattern 142p with the plurality of second openings 142 formed in the idle area 10b of the resist layer 14. Sizes and shapes of the second openings 142 may be the same or different depending on actual needs.

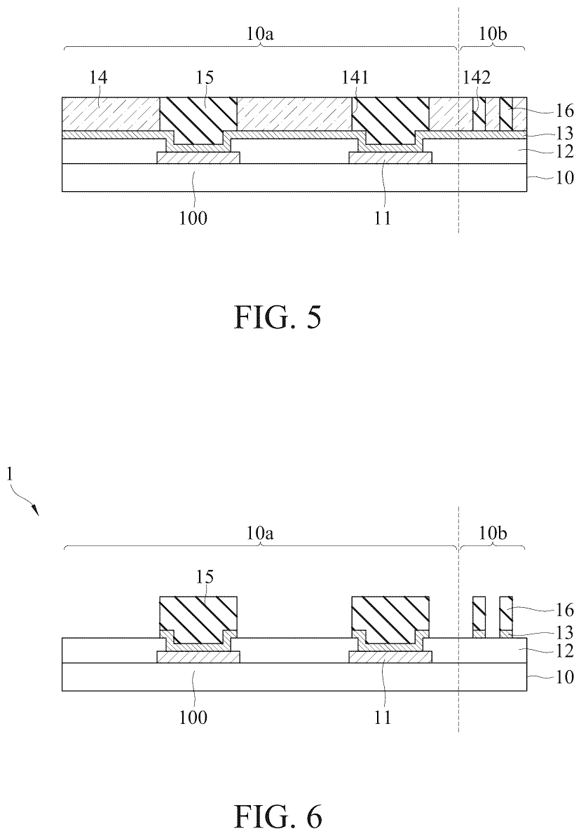

As shown in FIG. 5, via an electroplating process, a plurality of conductive bumps 15 are formed on the conductive layer 13 from which the plurality of first openings 141 are exposed, and a plurality of current control bumps 16 are formed on the conductive layer 13 from which the plurality of second openings 142 (the current control patterns 142p) are exposed.

Accordingly, under a conventional circumstance that a density of the plurality of electrical connection pads 11 in the electrical contact dense areas 100a is more than twice that in the electrical contact sparse areas 100b, uneven electroplating current distribution may occur. Compared with the afore-mentioned circumstance, the present disclosure forms the current control pattern 142p by additionally opening the plurality of second openings 142 in the resist layer 14 in the idle area 10b (non-complete chip area) to distribute the electroplating current. The density of the plurality of first openings 141 of the resist layer 14 in the electrical contact dense areas 100a is higher than the density of the plurality of second openings 142 (the current control pattern 142p) of the resist layer 14 in the idle area 10b, and the density of the plurality of second openings 142 (the current control pattern 142p) of the resist layer 14 in the idle area 10b is higher than the density of the plurality of first openings 141 of the resist layer 14 in the electrical contact sparse areas 100b. Therefore, a flatness problem of the conductive bumps 152 caused by current concentrated in the electrical contact sparse areas 100b can be prevented.

As shown in FIG. 6, the resist layer 14 and the conductive layer 13 covered by the resist layer 14 are then removed to obtain the semiconductor structure 1 of the present disclosure.

Via the above-mentioned manufacturing method, the present disclosure provides a semiconductor structure 1 of a monolithic structure, including: the semiconductor substrate 10 defined with the active area 10a and the idle area 10b. The plurality of semiconductor substrate units 100 are disposed on the active area 10a, and each of the semiconductor substrate units 100 is defined with the electrical contact dense area 100a and the electrical contact sparse area 100b; the plurality of conductive bumps 15 formed on each of the semiconductor substrate units 100 in the active area 10a; and the plurality of current control bumps 16 formed in the idle area 10b. The density of the plurality of conductive bumps 15 in the electrical contact dense areas 100a is higher than the density of the plurality of current control bumps 16 in the idle area 10b, and the density of the plurality of current control bumps 16 in the idle area 10b is higher than the density of the plurality of conductive bumps 15 in the electrical contact sparse areas 100b. For example, the density of the plurality of conductive bumps 15 in the electrical contact dense areas 100a is more than twice that in the electrical contact sparse areas 100b.

The semiconductor structure 1 further includes the plurality of electrical connection pads 11 which are only disposed in the active area 10a on each of the semiconductor substrate units but not disposed in the idle area 10b.

The semiconductor structure 1 further includes the insulating layer 12 disposed on the semiconductor substrate 10. The insulating layer 12 has the plurality of openings 120 to expose the plurality of electrical connection pads 11.

The semiconductor structure 1 further includes the conductive layer 13, the under-bump metallization, disposed on the insulating layer 12 and the electrical connection pads 11. The plurality of conductive bumps 15 are disposed on the conductive layer 13 corresponding to the plurality of electrical connection pads 11, and the current control bumps 16 are disposed on the conductive layer 13 corresponding to a portion of the insulating layer 12.

To sum up, in the semiconductor structure and the manufacturing method thereof according to the present disclosure, the plurality of first openings of the resist layer are formed in the active area of the semiconductor substrate, while the plurality of second openings of the resist layer are also formed in the idle area of the semiconductor substrate (forming the current control pattern) when the plurality of conductive bumps are formed by electroplating. Then, the plurality of current control bumps are formed by electroplating to distribute the electroplating current and to avoid inconsistencies in the height and flatness of the plurality of conductive bumps caused by uneven electroplating current distribution.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A semiconductor structure, comprising:
a semiconductor substrate defined with an active area and an idle area, wherein a plurality of semiconductor substrate units are disposed on the active area, and each of the semiconductor substrate units is defined with an electrical contact dense area and an electrical contact sparse area;
a plurality of conductive bumps formed on each of the semiconductor substrate units in the active area; and
a plurality of current control bumps formed on the idle area, wherein a density of the plurality of conductive bumps in the electrical contact dense areas is higher than a density of the plurality of current control bumps in the idle area, and a density of the plurality of current control bumps in the idle area is higher than a density of the plurality of conductive bumps in the electrical contact sparse areas.

2. The semiconductor structure of claim 1, further comprising a plurality of electrical connection pads disposed only on each of the semiconductor substrate units in the active area.

3. The semiconductor structure of claim 2, further comprising an insulating layer disposed on the semiconductor substrate, and the insulating layer formed with a plurality of openings to expose the plurality of electrical connection pads.

4. The semiconductor structure of claim 3, further comprising a conductive layer disposed on the insulating layer and the plurality of electrical connection pads.

5. The semiconductor structure of claim 4, wherein the conductive layer is an under-bump metallization.

6. The semiconductor structure of claim 4, wherein the plurality of conductive bumps are disposed on the conductive layer corresponding to the plurality of electrical connection pads.

7. The semiconductor structure of claim 4, wherein the plurality of current control bumps are disposed on the conductive layer corresponding to a portion of the insulating layer.

8. The semiconductor structure of claim 1, wherein a density of the plurality of conductive bumps in the electrical contact dense areas is more than twice that in the electrical contact sparse areas.

9. A method of manufacturing a semiconductor structure, comprising:
providing a semiconductor substrate defined with an active area and an idle area adjacent to each other, wherein a plurality of semiconductor substrate units are disposed on the active area, and each of the semiconductor substrate units is defined with an electrical contact dense area and an electrical contact sparse area;
forming a plurality of conductive bumps on each of the semiconductor substrate units in the active area; and
forming a plurality of current control bumps on the idle area, wherein a density of the plurality of conductive bumps in the electrical contact dense areas is higher than a density of the plurality of current control bumps in the idle area, and a density of the plurality of current control bumps in the idle area is higher than a density of the plurality of conductive bumps in the electrical contact sparse areas.

10. The method of claim 9, wherein a plurality of electrical connection pads are disposed on each of the semiconductor substrate units in the active area.

11. The method of claim 10, wherein an insulating layer is disposed on the semiconductor substrate, and the insulating layer is formed with a plurality of openings to expose the plurality of electrical connection pads.

12. The method of claim 11, further comprising forming a conductive layer on the insulating layer and the plurality of electrical connection pads.

13. The method of claim 12, wherein the conductive layer is an under-bump metallization.

14. The method of claim 12, further comprising forming a resist layer on the conductive layer, wherein a plurality of first openings are formed on the resist layer in the active area to expose the conductive layer corresponding to the plurality of electrical connection pads, and a plurality of second openings are formed on the resist layer in the idle area to form a current control pattern and expose the conductive layer corresponding to a portion of the insulating layer.

15. The method of claim 14, further comprising forming the plurality of conductive bumps in the plurality of first openings, and forming the plurality of current control bumps in the plurality of second openings.

16. The method of claim 15, further comprising removing the resist layer and the conductive layer covered by the resist layer.

17. The method of claim 9, wherein a density of the plurality of conductive bumps in the electrical contact dense areas is more than twice that in the electrical contact sparse areas.
